(19) United States
(12) Patent Application Publication
(10) Pub. No.: US 2024/0355857 A1
(43) Pub. Date: Oct. 24, 2024

(54) PHOTOELECTRIC CONVERSION APPARATUS, PHOTOELECTRIC CONVERSION SYSTEM, AND MOVING OBJECT

(71) Applicant: CANON KABUSHIKI KAISHA, Tokyo (JP)

(72) Inventors: YUSUKE ONUKI, Kanagawa (JP); JUNJI IWATA, Tokyo (JP); HAJIME IKEDA, Kanagawa (JP); YASUSHI MATSUNO, Kanagawa (JP)

(21) Appl. No.: 18/762,474

(22) Filed: Jul. 2, 2024

Related U.S. Application Data
(63) Continuation of application No. PCT/JP2022/000069, filed on Jan. 5, 2022.

(51) Int. Cl. H01L 27/146; H04N 25/705

(52) U.S. Cl. CPC H01L 27/14634; H01L 27/1461; H01L 27/14623; H01L 27/14636; H01L 27/14645; H04N 25/705

(57) ABSTRACT

A photoelectric conversion apparatus includes a first substrate having a first semiconductor element layer including a plurality of photoelectric conversion units, and a second substrate having a second semiconductor element layer. The first and second substrates are laminated. The first semiconductor element layer has an effective pixel region, an optical black (OB) pixel region, and an outer periphery region. The effective pixel region includes a photoelectric conversion unit having a larger light-shielded area than other photoelectric conversion units out of the plurality of photoelectric conversion units. The OB pixel region overlaps with a light-shielding region, but the outer periphery region does not overlap with the light-shielding region in a planar view. The outer periphery region is provided with an electric charge discharge region including a semiconductor region of the same conductivity type as signal electric charges. The electric charge discharge region is supplied with a fixed potential.

### CROSS-REFERENCE TO RELATED APPLICATIONS

This application is a Continuation of International Patent Application No. PCT/JP2022/000069, filed Jan. 5, 2022, which is hereby incorporated by reference herein in its entirety.

### BACKGROUND OF THE INVENTION

### Field of the Invention

The present invention relates to a photoelectric conversion apparatus, a photoelectric conversion system, and a moving object.

### Background Art

A photoelectric conversion apparatus is known to include an effective pixel region including a plurality of pixels, and a light-shielded optical black (OB) region disposed around the periphery of the effective pixel region. Patent Literature 1 discloses a rear-surface irradiation photoelectric conversion apparatus, where light is emitted from the surface opposite to the surface of a semiconductor substrate with a wiring layer disposed. According to Patent Document 1, electric charge discharge pixels for discharging signal electric charges leaking from the effective pixel region into between the effective pixel region and the OB region or into the OB region are disposed between the effective pixel region and the OB region. Signal electric charges leaking from the effective pixel region are forcibly discharged.

### CITATION LIST

### Patent Literature

PTL 1: Japanese Patent Application Laid-Open No. 2011-97418

Patent Literature 1 considers surplus electric charges entering the OB region from the effective pixel region but does not consider surplus electric charges entering the OB region from the periphery of the OB region. In a case where OB pixels are disposed at edges of the substrate as discussed in Patent Literature 1, if signal electric charges generated around the periphery of the OB region enter the OB region, a black level reference signal varies. Therefore, it is also necessary to prevent surplus electric charges from entering the OB region. In particular, a laminated photoelectric conversion apparatus eliminates the need of disposing signal processing circuits for processing signals output from pixels, around the periphery of the OB region, notably providing effects of the present invention to a further extent.

### SUMMARY OF THE INVENTION

Patent Literature 1 does not consider a case where a plurality of photoelectric conversion units disposed in the effective pixel region includes a photoelectric conversion unit having a larger light-shielded region than other photoelectric conversion units.

The present invention is directed to providing a laminated photoelectric conversion apparatus capable of preventing surplus electric charges from entering the OB region and more accurately detecting the black level reference signal.

A photoelectric conversion apparatus includes a first substrate having a first semiconductor element layer including a plurality of photoelectric conversion units and a well with the plurality of photoelectric conversion units disposed, and a second substrate having a second semiconductor element layer including a circuit for processing signals acquired by the plurality of photoelectric conversion units, wherein the first and second substrates are laminated, wherein the first semiconductor element layer has an effective pixel region having the plurality of photoelectric conversion units, an optical black pixel region disposed between the effective pixel region and an edge of the first semiconductor element layer, having the plurality of photoelectric conversion units, and an outer periphery region disposed between the optical black pixel region and the edge of the first semiconductor element layer, wherein the effective pixel region includes a photoelectric conversion unit having a larger light-shielded area than other photoelectric conversion units out of the plurality of photoelectric conversion units, wherein the optical black pixel region overlaps with a light-shielding region including a light-shielding layer, but the outer periphery region does not overlap with the light-shielding region in a planar view, wherein the outer periphery region is provided with an electric charge discharge region including a semiconductor region of the same conductivity type as signal electric charges, and wherein the electric charge discharge region is supplied with a fixed potential.

Further features of the present invention will become apparent from the following description of exemplary embodiments with reference to the attached drawings.

### BRIEF DESCRIPTION OF THE DRAWINGS

FIG. 1 is a schematic view illustrating different semiconductor substrates of a photoelectric conversion apparatus according to a first exemplary embodiment.

FIG. 2 is a schematic plan view illustrating a semiconductor substrate according to the first exemplary embodiment.

FIG. 3 is a schematic cross-sectional view taken along an X-X′ line of FIG. 2.

FIG. 4 is a schematic plan view illustrating a semiconductor substrate according to a second exemplary embodiment.

FIG. 5 is a schematic cross-sectional view taken along the X-X′ line of FIG. 4.

FIG. 6 is a schematic plan view illustrating a semiconductor substrate according to a third exemplary embodiment.

FIG. 7 is a schematic cross-sectional view taken along the X-X′ line of FIG. 6.

FIG. 8 is a schematic cross-sectional view illustrating a photoelectric conversion apparatus according to a fourth exemplary embodiment.

FIG. 9 is a schematic cross-sectional view illustrating a photoelectric conversion apparatus according to a fifth exemplary embodiment.

FIG. 10 is a schematic cross-sectional view illustrating a photoelectric conversion apparatus according to a sixth exemplary embodiment.

FIG. 11 is a schematic plan view illustrating a light-shielding layer of the photoelectric conversion apparatus according to the sixth exemplary embodiment.

FIG. 12 is a schematic plan view illustrating another example of the light-shielding layer of the photoelectric conversion apparatus according to the sixth exemplary embodiment.

FIG. 13 illustrates an equivalent circuit of pixels according to a seventh exemplary embodiment.

FIG. 14A illustrates a configuration of a pixel according to the seventh exemplary embodiment.

FIG. 14B illustrates another configuration of a pixel according to the seventh exemplary embodiment.

FIG. 14C illustrates still another configuration of a pixel according to the seventh exemplary embodiment.

FIG. 15 is a schematic cross-sectional view illustrating a photoelectric conversion apparatus according to the seventh exemplary embodiment.

FIG. 16 is a schematic cross-sectional view illustrating the photoelectric conversion apparatus according to the seventh exemplary embodiment.

FIG. 17 is a block diagram illustrating a photoelectric conversion system according to an eighth exemplary embodiment.

FIG. 18A is a block diagram illustrating a photoelectric conversion system according to a ninth exemplary embodiment.

FIG. 18B is another block diagram illustrating the photoelectric conversion system according to the ninth exemplary embodiment.

FIG. 19 a flowchart illustrating processing of the photoelectric conversion system according to the ninth exemplary embodiment.

### DESCRIPTION OF THE EMBODIMENTS

The following exemplary embodiments are not intended to limit the present invention but intended to embody the technical concepts of the present invention. In each drawing, the sizes and positional relations of members may be emphasized to clarify the descriptions. In the following descriptions, identical components are assigned the same reference numerals, and redundant descriptions thereof may be omitted.

In the following descriptions, an N-type semiconductor region refers to a semiconductor region of the first conductivity type including major carriers of the same conductivity type as signal electric charges, and a P-type semiconductor region refers to a semiconductor region of the second conductivity type. The present invention is also applicable to a case where holes serve as signal electric charges. In this case, a P-type semiconductor region refers to a semiconductor region of the first conductivity type including major carriers of the same conductivity type as signal electric charges, and an N-type semiconductor region refers to a semiconductor region of the second conductivity type.

According to the present specification and appended claims, the term “impurity density” simply used means the net impurity density that has been compensated by the impurity of the opposite conductivity type. More specifically, the term “impurity density” refers to the NET doping density. A region where the P-type additive impurity density is higher than the N-type additive impurity density is a P-type semiconductor region. Conversely, a region where the N-type additive impurity density is higher than the P-type additive impurity density is an N-type semiconductor region.

According to the present specification, “planar view” refers to viewing in the direction perpendicular to the light-incident surface of a semiconductor substrate (described below). “Cross-section” refers to the surface perpendicular to the light-incident surface of the semiconductor substrate. If the light-incident surface of the semiconductor substrate is microscopically viewed as a rough surface, a planar view is defined with reference to a macroscopically viewed light-incident surface of the semiconductor substrate.

According to the present specification, the depth direction refers to the direction from the light-incident surface (first surface) of the semiconductor substrate to the surface (second surface) mounted with transistors.

### First Exemplary Embodiment

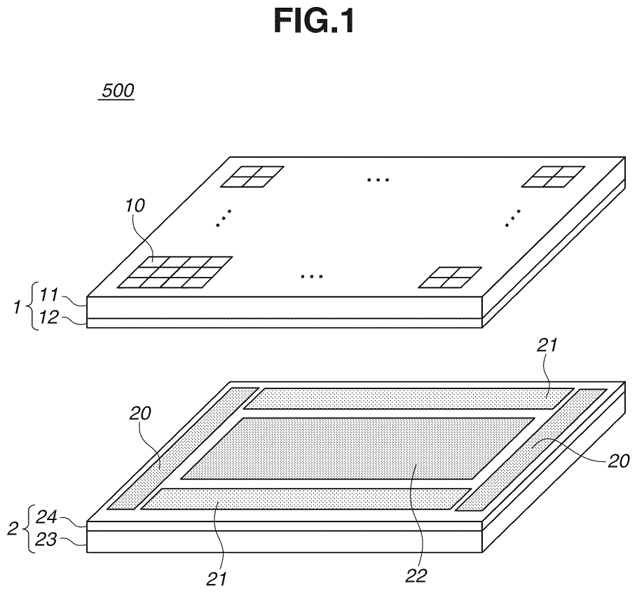

FIG. 1 illustrates a photoelectric conversion apparatus 500 according to a first exemplary embodiment. The photoelectric conversion apparatus 500 is a semiconductor device integrated circuit (IC). Examples of applications of the photoelectric conversion apparatus 500 according to the present exemplary embodiment include an image sensor, a photometry sensor, and a range-finding sensor.

The photoelectric conversion apparatus 500 is a laminated photoelectric conversion apparatus where substrates 1 and 2 are entirely or partially laminated and bonded. After the substrates 1 and 2 are laminated, the wafer may be diced into chips or the substrates may be left in the wafer state. The photoelectric conversion apparatus 500 is a laminated rear-surface irradiation photoelectric conversion apparatus.

The substrate 1 is formed of a semiconductor element layer 11 (first semiconductor element layer) including pixel circuits included in pixels 10, and a wiring structure 12 (first wiring structure). According to the present specification, a “semiconductor element layer” includes not only a semiconductor layer but also transistor gates formed in the semiconductor layer. A wiring layer having a wiring structure is not included in the “semiconductor element layer”. The substrate 2 is formed of a wiring structure 24 (second wiring structure), and a semiconductor element layer 23 (second semiconductor element layer) including electrical circuits. The wiring structure 12 of the substrate 1 and the wiring structure 24 of the substrate 2 are bonded with a metal bonding portion formed of bonded wiring layers included in the two wiring structures (described below). The metal bonding portion is a structure in which the constituent metal of one wiring layer is directly bonded with the constituent metal of the other wiring layer.

As described in detail below, elements of the pixels 10 are arranged in the semiconductor element layer 11. One part of components of the pixels 10 may be disposed in the semiconductor element layer 11, and the other part thereof may be disposed in the semiconductor element layer 23. In this case, examples of components of pixel circuits disposed in the semiconductor element layer 11 out of the pixels 10 include photoelectric conversion elements such as photodiodes. Pixel circuits including photoelectric conversion elements are disposed in the semiconductor element layer 11 in the form of a two-dimensional array in a plan view. The semiconductor element layer 11 has a pixel region disposed with a plurality of pixel circuits in the form of a two-dimensional array. Referring to FIG. 1, the semiconductor element layer 11 is disposed with a plurality of photoelectric conversion elements as components of the plurality of pixel circuits in the form of a two-dimensional array in the row and column directions.

The wiring structure 12 includes M wiring layers (M is one or a larger integer) and interlayer insulation materials. The wiring structure 24 includes N wiring layers (N is one or a larger integer) and interlayer insulation materials.

The semiconductor element layer 23 includes electrical circuits for processing signals obtained by the photoelectric conversion units disposed in the semiconductor element layer 11. Referring to FIG. 1, for convenience of description, the components illustrated on the upper surface of the substrate 2 are components disposed in the semiconductor element layer 23. An electrical circuit refers to any one of transistors that form a row scanning circuit 20, a column scanning circuit 21, and a signal processing circuit 22 illustrated in FIG. 1. For example, the signal processing circuit 22 refers to at least any one of a part of the components of a pixel 10 (such as an amplification transistor, a selection transistor, and a reset transistor), an amplification circuit, a selection circuit, a logical operation circuit, an analog-to-digital (A/D) conversion circuit, a memory, and a circuit performing compression or combining processing.

The pixel 10 may refer to the minimum unit of a circuit that is repetitively arranged to form an image. Each of pixel circuits included in the pixel 10 and disposed in the semiconductor element layer 11 needs to include at least a photoelectric conversion element. A pixel circuit may include components other than a photoelectric conversion element. For example, the pixel circuit may further include at least any one of a transfer transistor, a floating diffusion (FD), a reset transistor, an amplification transistor, a capacitance addition transistor, and a selection transistor. Typically, the pixel 10 is formed of a selection transistor, and a set of elements connected to signal lines via the selection transistor. More specifically, the selection transistor can be an outer edge of the pixel circuit. Alternatively, the pixel 10 may include a set of a photoelectric conversion element and a transfer transistor. In addition, the pixel 10 may include a set of one or a plurality of photoelectric conversion elements and one amplification circuit or one A/D conversion circuit.

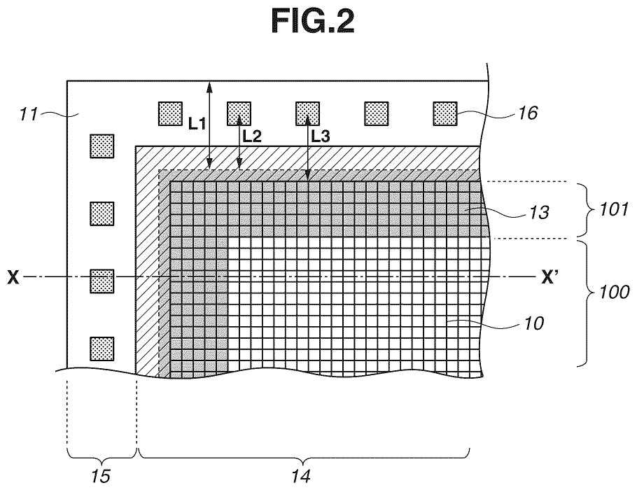

FIG. 2 is a schematic plan view illustrating edges of the semiconductor element layer 11 according to the first exemplary embodiment. The pixel region of the semiconductor element layer 11 includes an effective pixel region 100 disposed with effective pixels using incident signal electric charges as a signal, and an optical black pixel region 101 disposed with optical black pixels (OB pixels) for detecting a black level reference value. The OB pixel region 101 is disposed around the periphery of the effective pixel region 100 in a planar view, and includes a light-shielding layer 13 for shielding the light incident on the photoelectric conversion units in the OB pixel region 101. In other words, the OB pixel region 101 overlaps with a light-shielding region formed of the light-shielding layer 13 in a planar view. The term “periphery” is not limited to the entire circumference. The OB pixel region 101 only needs to be disposed on at least any one of the left, right, top, and bottom sides of the effective pixel region 100. In the following descriptions, the term “periphery” also includes a partial circumference unless otherwise described. The term “light-shielding” is not limited to 100% light shielding. For example, the term refers to light shielding of 50% or higher.

The semiconductor element layer 11 is internally disposed of a well region 14, and an outer periphery region 15 disposed around the periphery of the well region 14. The outer periphery region 15 does not overlap with the light-shielding region formed of the light-shielding layer 13 in a planar view. Although, according to the present exemplary embodiment, the outer periphery region 15 and the light-shielding region do not completely overlap with each other in a planar view, the two regions may partially overlap with each other as in an exemplary embodiment (described below). At least a part of the pixels 10 is formed in the well region 14. The outer periphery region 15 is disposed with pads 16.

The pads 16 are disposed between each edge of the semiconductor element layer 11 and the well region 14. A minimum distance L1 between the edge of the semiconductor element layer 11 and the light-shielding layer 13 is, for example, 100 μm or more and 250 μm or less and preferably is 100 μm or more and 150 μm or less in a planar view. A minimum distance L2 between the center of each pad 16 and the light-shielding layer 13 is, for example, 30 μm or more and 200 μm or less and preferably is 50 μm or more and 100 μm or less in a planar view. To avoid a defective formation due to a manufacturing error in pad formation, the above-described distances need to be equal to or larger than predetermined distances. To increase the area of the effective pixel region 100 without increasing the area of the semiconductor element layer 11, preferably, these distances are equal to or less than predetermined distances. The center of the pad 16 refers to the center of the trench of the pad 16. As described in detail below, shorter distance between the center of the pad 16 and the OB pixel region 101 will notably provide effects of the present exemplary embodiment to a further extent. A minimum distance L3 between the center of the pad 16 and a pixel 10 in the OB pixel region 101 is, for example, 100 μm or more and 500 μm or less, and is preferably 250 μm or more and 350 μm or less.

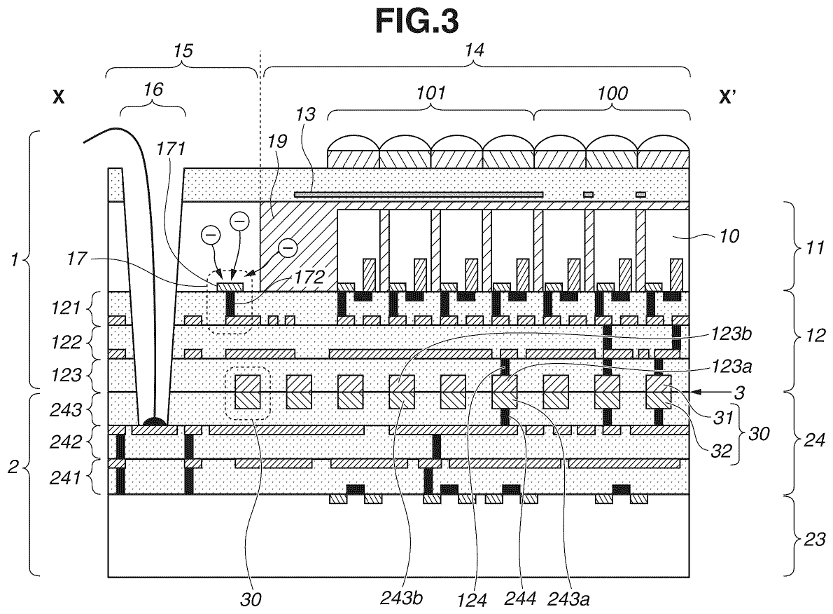

FIG. 3 is a schematic cross-sectional view taken along the X-X′ line of FIG. 2. The substrates 1 and 2 are bonded and laminated on a bonding surface 3. The wiring structure 12 of the substrate 1 and the wiring structure 24 of the substrate 2 are positioned between the semiconductor element layer 11 of the substrate 1 and the semiconductor element layer 23 of the substrate 2. Referring to FIG. 3, the wiring structure 12 includes three different wiring layers 121, 122, and 123, and the wiring structure 24 includes three different wiring layers 241, 242, and 243.

The wiring structure 12 includes three different wiring layers 121, 122, and 123 which can be, for example, Cu wiring layers. Referring to FIG. 3, the wiring layer 123 includes metal portions 31 of metal bonding portions 30. Each of the metal bonding portions 30 embedded in a concave portion formed in an interlayer insulation film has a damascene structure.

The wiring structure 24 has three different wiring layers 241, 242, and 243 which can be Cu wiring layers. Referring to FIG. 3, the wiring layer 243 includes metal portions 32 of the metal bonding portions 30. Each of the metal portions 32 embedded in a concave portion formed in an interlayer insulation film has a damascene structure.

The wiring layers 123 and 243 are bonded to (brought into contact with) each other by the interlayer insulation film having a concave portion embedded with the metal portion 31, the interlayer insulation film having a concave portion embedded with the metal portion 32, and the metal portions 31 and 32. The metal bonding portion 30 is formed of the metal portions 31 and 32 bonded to each other.

A via plug 124 formed in the interlayer insulation film of the wiring layer 123 makes an electrical connection between the metal portion 31 and the wiring layer 122. A via plug 244 formed in the interlayer insulation film of the wiring layer 243 makes an electrical connection between the metal portion 32 and the wiring layer 242. The metal bonding portion 30 connecting with the via plugs 124 and 244 makes an electrical connection between the semiconductor element layers 11 and 23.

For example, the wiring layer 123 includes a wiring pattern 123a connected with a wiring pattern of the upper wiring layer, and a wiring pattern 123b not connected with a wiring pattern of the upper wiring layer. The wiring layer 243 includes a wiring pattern 243a connected with a wiring pattern of the lower wiring layer, and a wiring pattern 243b not connected with a wiring pattern of the lower wiring layer. Referring to FIG. 3, for example, the wiring pattern 123a is connected with a wiring pattern of the upper wiring layer via the via plug 124, and the wiring pattern 243a is connected with a wiring pattern of the lower wiring layer via the via plug 244. Since the via plugs may be dispensable, the wiring pattern 123a or 243a may be directly connected with a wiring pattern of the upper or lower wiring layer.

Referring to FIG. 3, the wiring patterns 123a and 243a make an electrical connection between the semiconductor element layers 11 and 23. Not all of the wiring patterns 123a and 243a need to be connected with the semiconductor element layers 11 and 23, respectively. A part of the wiring patterns 123a and 243a may be connected with the semiconductor element layers 11 and 23, respectively. A part of the wiring patterns 123a and 243a may be connected with certain wiring layers, and connected with neither the semiconductor element layer 11 nor 23.

As illustrated in FIG. 3, the semiconductor element layer 11 includes the well region 14 disposed with a well 19, and the outer periphery region 15 disposed between an edge of the semiconductor element layer 11 and the well region 14. For example, the well 19 is a region with P-type impurity ions injected, and the outer periphery region 15 is a region with the well 19 not disposed. The outer periphery region 15 is an N-type semiconductor region, or a region having a lower P-type impurity density than the well 19.

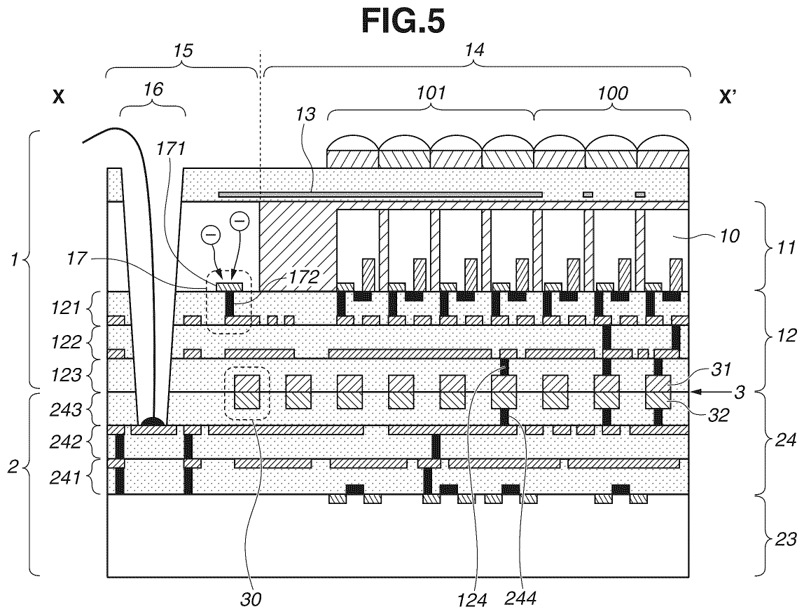

The well 19 is disposed with a plurality of photoelectric conversion units of the effective pixel region 100 and a plurality of photoelectric conversion units of the OB pixel region 101. The well region 14 is disposed with the effective pixel region 100 and the OB pixel region 101. The OB pixel region 101 is disposed with the light-shielding layer 13 on the side of the light-incident surface of the semiconductor element layer 11. For example, the light-shielding layer 13 is disposed on the light-incident surface of the semiconductor element layer 11 via an insulating material. Microlenses are disposed on the side of the light-incident surface of the semiconductor element layer 11 via an insulating material. Referring to FIG. 5, color filters are disposed between the microlenses and the insulating material. The arrangements of the color filters can be suitably selected. The color filters may be arranged, for example, in a Bayer array. A plurality of photoelectric conversion units may be disposed with respect to each microlens. Although, referring to FIG. 3, microlenses is also disposed in the OB pixel region 101, the microlenses are not essential. No microlens may be disposed at positions overlapping with the light-shielding layer 13 in a planar view. As illustrated in FIG. 3, the light-shielding layer 13 may be disposed between a pixel 10 and an adjacent pixel 10 in a planar view in the effective pixel region 100. This enables reducing a crosstalk between the pixels 10 in the effective pixel region 100.

The outer periphery region 15 is disposed with the pads 16. As illustrated in FIG. 2, the outer periphery region 15 is disposed with a plurality of the pads 16. The plurality of the pads 16 makes an electrical connection between the photoelectric conversion apparatus 500 and a signal processing apparatus disposed outside the photoelectric conversion apparatus 500. The plurality of the pads 16 includes pads for outputting signals from the photoelectric conversion apparatus 500 to the outside and pads for inputting a power voltage to the photoelectric conversion apparatus 500.

As illustrated in FIG. 3, a trench is formed as the pad 16 at the edge of the semiconductor element layer 11. The trench is formed in the depth direction from the light-incident surface of the semiconductor element layer 11 up to the depth reaching the wiring patterns of the wiring layer 242 of the substrate 2. The pad 16 is electrically connected with the wiring layer 242 formed in the substrate 2, through wire bonding.

The wiring layer 242 can be an Al wiring layer. Not the entire wiring layer 242 needs to be an Al wiring layer. Only wirings connected with the pads 16 may be Al wirings and other wirings may be Cu wirings. Although wire bonding is used in this example, a through-via (TSV) where the trench is filled with a metal is also applicable.

The trench of each pad 16 may be formed with a depth reaching the wiring layers of the substrate 1.

Since a trench needs to be formed for the pad 16 as described above, the light-shielding layer 13 cannot be to the proximity of the pad 16. With a rear-surface irradiation photoelectric conversion apparatus, the thickness (length in the depth direction) of the semiconductor element layer 11 is likely to be smaller than that for a front-surface incidence photoelectric conversion apparatus. For example, the thickness of the semiconductor element layer 11 is 11 μm or less. Therefore, long-wavelength light such as infrared light incident on the light-incident surface of the semiconductor element layer 11 is reflected by the surface on the side where transistors are formed, possibly generating surplus electric charges. Particularly in the configuration of a laminated rear-surface irradiation photoelectric conversion apparatus where scanning circuits, digital processing circuits, and other peripheral circuits not mounted on the substrate 1, the distance between the edge of the substrate 1 and the OB pixel region 101 is short, as illustrated in FIG. 3. In other words, in the configuration of the laminated rear-surface irradiation photoelectric conversion apparatus, no circuit element is disposed between the pad 16 and the well 19. Therefore, if light is incident on non-light-shielding regions such as a part of the well region 14 and the outer periphery region 15, electric charges may be generated by the photoelectric conversion. If surplus electric charges generated in the non-light-shielding regions enter the OB pixel region 101 via the well region 14, the black level reference value cannot be correctly detected, making it impossible to correct pixel values in the effective pixel region 100.

According to the present exemplary embodiment, therefore, a drain portion 17 for discharging surplus electric charges is provided in the outer periphery region 15. The drain portion 17 functions as an electric charge discharge region for discharging surplus electric charges. The drain portion 17 is disposed with a semiconductor region 171 of the same conductivity type as the outer periphery region 15. The semiconductor region 171 is formed by injecting impurity ions of the same conductivity type as the outer periphery region 15. The semiconductor region 171 has a higher impurity density than the outer periphery region 15. A contact plug 172 is formed in the semiconductor region 171. A fixed potential is applied to the drain portion 17 via the wiring layer 121 and the contact plug 172. For example, if the outer periphery region 15 is an N-type region and the well region 14 is a P-type region, a power voltage having a positive potential is applied to the drain portion 17. If the outer periphery region 15 is a P-type region and the well region 14 is an N-type region, a power voltage having a negative potential is applied to the drain portion 17. For example, if the outer periphery region 15 a P-type region, a ground potential is applied to the drain portion 17. This enables discharging surplus electric charges from the drain portion 17. Electric charges can be prevented from entering the OB pixel region 101 by providing a potential difference between the drain portion 17 and the well region 14. Likewise, electric charges generated as a dark current at an edge of the substrate can also be prevented from entering the OB pixel region 101, thus enabling accurate detection of the black level reference value.

Preferably, the semiconductor region 171 and the well 19 are disposed as closely to each other as possible. For example, preferably, the distance between the semiconductor region 171 and the well 19 is 0 μm or more and 100 μm or less. This makes it easier to prevent surplus electric charges such as electric charges generated by the photoelectric conversion near the well 19 in the outer periphery region 15 and noise electric charges (dark current) from entering the OB pixel region 101 through the well 19.

The wiring pattern of the wiring layer 121 connected with the drain portion 17 may be common to the wiring pattern supplied to the drains of transistors of the pixels 10. For example, the wiring pattern supplied with the power voltage VDD of the reset transistor may be common to the wiring pattern supplied with the power voltage VDD to be supplied to the drain portion 17.

Referring to FIG. 2, the pads 16 are disposed between the top edge of the semiconductor element layer 11 and the well region 14 and between the left edge of the semiconductor element layer 11 and the well region 14 in a planar view. The pads 16 may be disposed between the bottom edge of the semiconductor element layer 11 and the well region 14 and between the right edge of the semiconductor element layer 11 and the well region 14 in a planar view. In other words, the outer periphery region 15 with the pads 16 may be disposed so as to surround the entire circumference of the well region 14 of the semiconductor element layer 11 in a planar view. In such a case, the area of the region between the OB pixel region 101 and the outer periphery region 15, where the light-shielding layer 13 is not disposed, is likely to increase. This notably enables obtaining an effect of more accurately detecting the black level reference value. It is not essential that the pads 16 are disposed so as to surround the entire circumference of the well region 14 of the semiconductor element layer 11 in a planar view. Even if the pads 16 are not disposed in this way, the effect of the present invention can be obtained as long as the pads 16 are disposed in at least a part of the region between an edge of the semiconductor element layer 11 and the well region 14 in a planar view. For example, the pads 16 may be disposed between the top edge of the semiconductor element layer 11 and the well region 14 but not disposed between the left edge of the semiconductor element layer 11 and the well region 14 in a planar view. Even this case enables obtaining an effect of more accurately detecting the black level reference value.

### Second Exemplary Embodiment

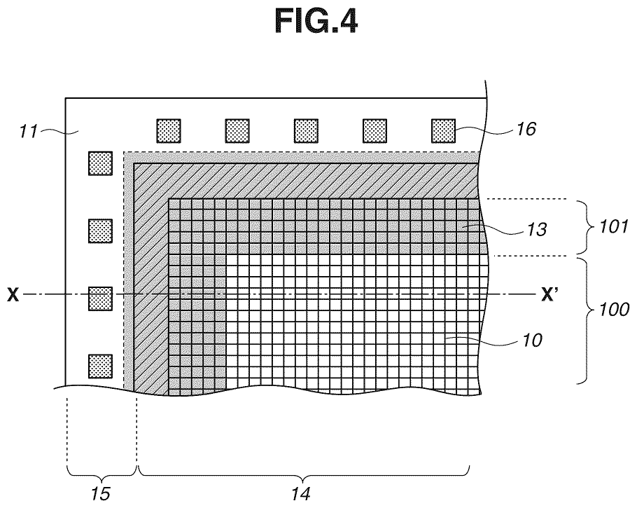

FIG. 4 is a schematic plan view illustrating edges of the semiconductor element layer 11 according to a second exemplary embodiment. FIG. 5 is a schematic cross-sectional view taken along the X-X′ line of FIG. 4. The second exemplary embodiment differs from the first exemplary embodiment in that the light-shielding layer 13 is disposed so as to cover the well region 14. The present exemplary embodiment is substantially the same as the first exemplary embodiment except for this point and the following point, and redundant descriptions thereof will be omitted.

As illustrated in FIG. 5, according to the present exemplary embodiment, the light-shielding layer 13 is disposed so as to partially overlap with the outer periphery region 15 in a planar view. More specifically, the light-shielding layer 13 projects from the edge of the well region 14 toward the pad 16 in a cross-sectional view.

According to the first exemplary embodiment, since the well region 14 is not partially light-shielded, surplus electric charges generated by the photoelectric conversion in the well region 14 may possibly enter the proximal OB pixel region 101. On the other hand, according to the second exemplary embodiment, since the well region 14 is light-shielded, the photoelectric conversion is not performed in the well region 14. In other words, the well 19 is not exposed from the light-shielding region in a planar view. More specifically, the edge of the well 19 and the edge of the light-shielding layer 13 are at the same position, or the edge of the light-shielding layer 13 projects more than the edge of the well 19 toward the side of the semiconductor element layer 11 in a planar view. In such a case, at the edge of the semiconductor element layer 11, surplus electric charges are generated only in the outer periphery region 15 of the non-light-shielding region. Surplus electric charges are discharged by the drain portion 17 disposed in the outer periphery region 15. Therefore, the present exemplary embodiment enables preventing electric charges from entering the OB pixel region 101 to a further extent than the first exemplary embodiment, thus enabling more accurately detecting the black level reference value.

### Third Exemplary Embodiment

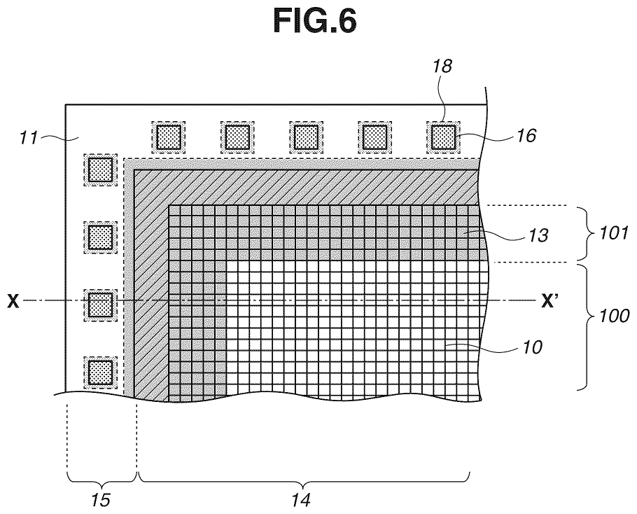

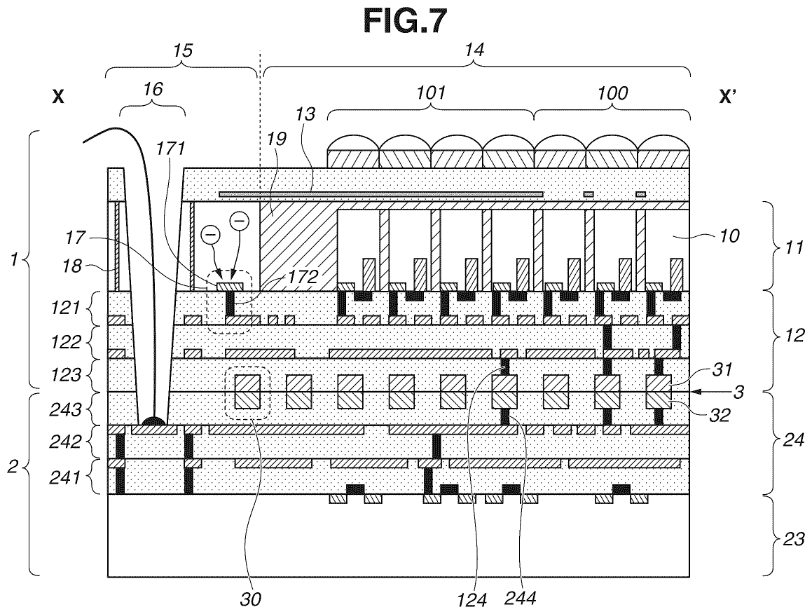

FIG. 6 is a schematic plan view illustrating edges of the semiconductor element layer 11 according to a third exemplary embodiment. FIG. 7 is a schematic cross-sectional view taken along the X-X′ line of FIG. 6. The third exemplary embodiment differs from the second exemplary embodiment in that a separation region 18 is disposed around each pad 16 in the semiconductor element layer 11. The present exemplary embodiment is substantially the same as the second exemplary embodiment except for this point and the following point, and redundant descriptions thereof will be omitted.

The separation region 18 is disposed so as to surround the entire circumference of the pad 16 in a planar view. The separation region 18 is an element separating portion as a trench formed in the semiconductor element layer 11 and filled with an insulation film such as a silicone oxide film or a silicon nitride film.

According to the second exemplary embodiment, if the wire bonding comes into contact with the side surface of the trench of the pad 16 in the semiconductor element layer 11 where the pads 16 are formed, a short-circuit will occur between the wire bonding and the outer periphery region 15 subjected to voltage application. According to the third exemplary embodiment, on the other hand, the separation region 18 separates the outer periphery region 15 in the vicinity of the trench of the pad 16 and in the vicinity of the well 19. More specifically, the separation region 18 insulates the side surface of the trench in the semiconductor element layer 11 where the pad 16 is formed, from the outer periphery region 15, which is subjected to voltage application, with the drain portion 17 disposed. This enables avoiding a short-circuit between the wire bonding and the outer periphery region 15 while more accurately detecting the black level reference value like the second exemplary embodiment.

### Fourth Exemplary Embodiment

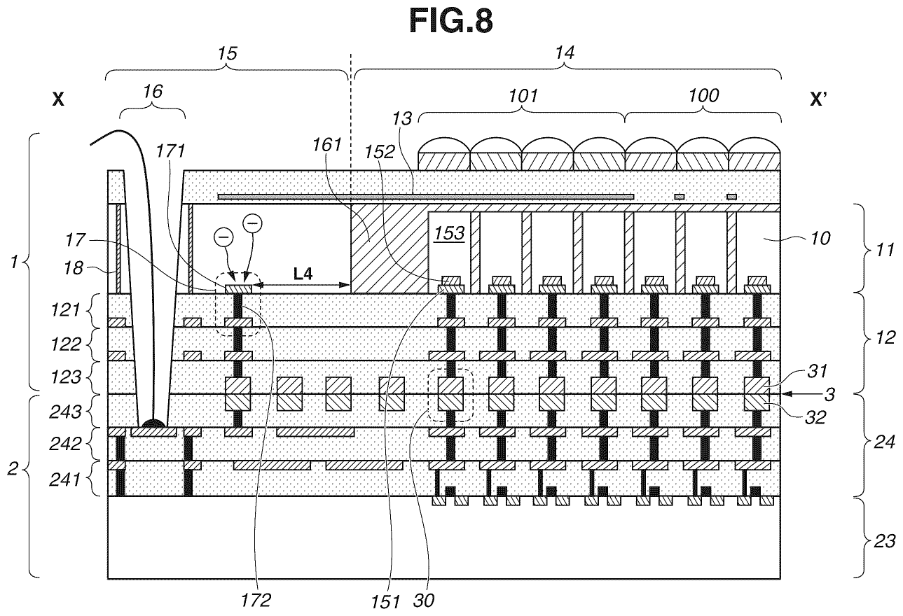

FIG. 8 is a schematic cross-sectional view illustrating a laminated rear-surface irradiation photoelectric conversion apparatus according to a fourth exemplary embodiment. The fourth exemplary embodiment differs from the third exemplary embodiment in that the semiconductor element layer 11 includes an avalanche photodiode (hereinafter referred to as an APD). The present exemplary embodiment also differs from the third exemplary embodiment in that that a distance L4 between a semiconductor region 161 of the second conductivity type to which an APD drive voltage is applied and the semiconductor region 171 discharging surplus electric charges is larger than the distance between the well 19 and the semiconductor region 171 according to the third exemplary embodiment. The present exemplary embodiment is substantially the same as the third exemplary embodiment except for these points and the following point, and redundant descriptions thereof will be omitted.

The APD disposed in the substrate 1 includes a semiconductor region 151 of the first conductivity type and a semiconductor region 152 of the second conductivity type. Electric charges subjected to the avalanche multiplication are sent to the substrate 2 via the metal bonding portion 30. The substrate 2 is disposed with a quench circuit and a counter circuit, and signals are sent to the counter circuit of the substrate 2 via the metal bonding portion 30. Therefore, the metal bonding portion 30 for connecting the semiconductor element layers 11 and 23 is disposed for each APD.

To drive the APD, a high voltage needs to be applied to the semiconductor region 152 of the second conductivity type. The difference between the voltage applied to the semiconductor region 151 and the voltage applied to the semiconductor region 152 is, for example, is 20 V or more. An example of a voltage applied to the semiconductor region 152 is a negative voltage having a larger absolute value than −20 V. The voltage applied to the semiconductor region 152 is supplied from the semiconductor region 161 of the second conductivity type via a semiconductor region 153 of the second conductivity type. Therefore, the above-described high voltage is applied to the semiconductor region 161 of the second conductivity type.

The semiconductor region 171 for discharging surplus electric charges is formed with the first conductivity type. Therefore, if the semiconductor region 171 is close to the semiconductor region 161 of the second conductivity type, an avalanche multiplication region is formed between the semiconductor regions 161 and 171. More specifically, an avalanche multiplication region is formed in a region other than the pixel region, and surplus electric charges may be subjected to the avalanche multiplication and then enter the OB pixel region 101.

Therefore, if an APD is disposed as a photoelectric conversion unit in the substrate 1, the distance L4 between the semiconductor region 161 of the second conductivity type surrounding the pixel region and the semiconductor region 171 of the first conductivity type needs to be set so that no avalanche multiplication occurs.

According to the present exemplary embodiment, the distance L4 as a relatively large distance enables accurately detecting the black level reference value while preventing the formation of an avalanche multiplication region between the semiconductor regions 161 and 171.

For example, the distance L4 can be 1 μm or more and 10 μm or less and preferably is 3 μm or more and 6 μm or less.

As illustrated in FIG. 8, the semiconductor region 171 and the light-shielding layer 13 may overlap with each other in a planar view.

### Fifth Exemplary Embodiment

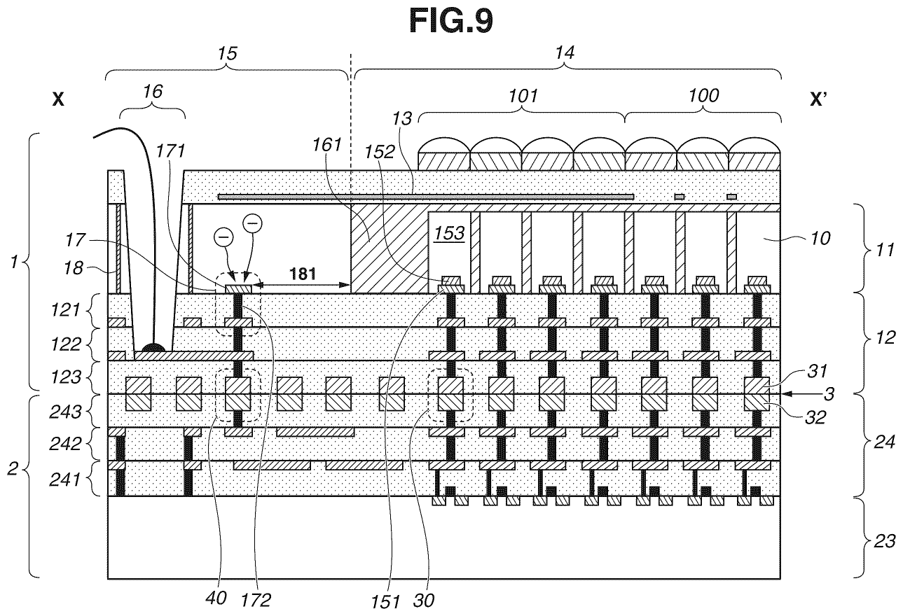

FIG. 9 is a schematic cross-sectional view illustrating a laminated rear-surface irradiation photoelectric conversion apparatus according to a fifth exemplary embodiment. The fifth exemplary embodiment differs from the fourth exemplary embodiment in that the drain portion 17 is connected with the pad 16 in the same substrate. The present exemplary embodiment is substantially the same as the fourth exemplary embodiment except for this point and the following point, and redundant descriptions thereof will be omitted.

According to the present exemplary embodiment, the trench of the pad 16 is formed with a depth reaching the wiring pattern of the wiring layer 122 of the substrate 1, and the wiring pattern of the wiring layer 122 is connected with the bonding wire. The wiring pattern connected with the bonding wire and the drain portion 17 are connected via the contact plug 172 and the wiring pattern of the wiring layer 121.

As described above with reference to the fourth exemplary embodiment, if an APD is disposed as a photoelectric conversion unit in the substrate 1, a high voltage for driving the APD is required. However, from the viewpoint of the dielectric strength, it is not desirable to apply the above-described high voltage for driving the APD to the semiconductor element layer 23 of the substrate 2 that is generally formed in a fine process. Therefore, preferably, the high voltage for driving the APD is supplied from the pad 16 disposed in the substrate 1. In this case, surplus electric charges drained from the drain portion 17 of the substrate 1 are discharged out of the photoelectric conversion apparatus via the pad 16 disposed in the substrate 1.

If the depth of the trench of the pad 16 for supplying the voltage for driving an element disposed in the substrate 2 is different from the depth of the trench of the pad 16 for supplying the voltage for driving an APD disposed in the substrate 1, the manufacturing process becomes complicated, possibly resulting in an increase in difficulty in the process.

According to the present exemplary embodiment, preferably, the voltage for driving elements disposed in the substrate 2 is applied to the pad 16 formed in the substrate 1 and then supplied to the semiconductor element layer 23 of the substrate 2 via the metal bonding portion 40.

Like the fourth exemplary embodiment, the present exemplary embodiment enables accurately detecting the black level reference value while preventing the formation of an avalanche multiplication region between the semiconductor regions 161 and 171. Since a high voltage is not applied to the semiconductor element layer 23 of the substrate 2, the reliability of the photoelectric conversion apparatus can be easily ensured when the APD is used.

### Sixth Exemplary Embodiment

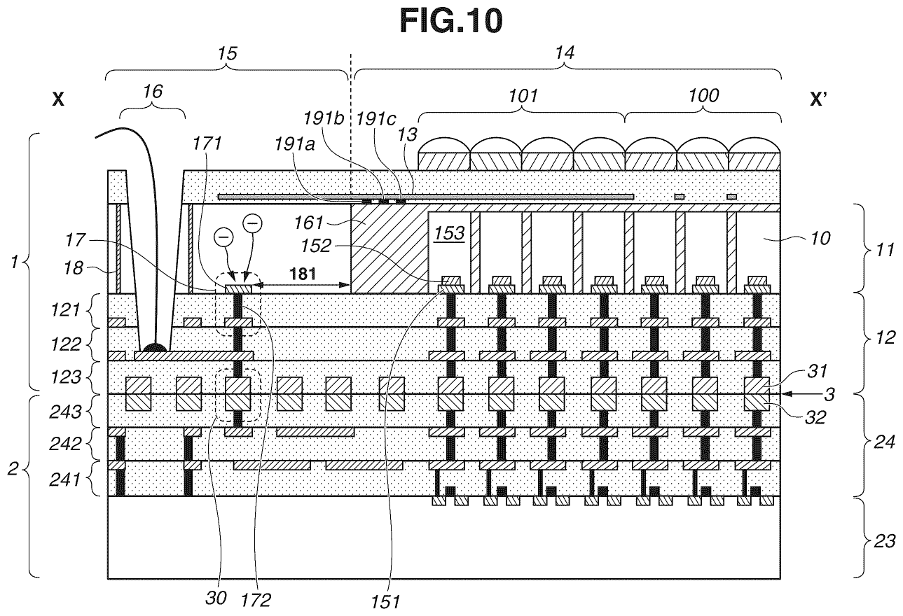

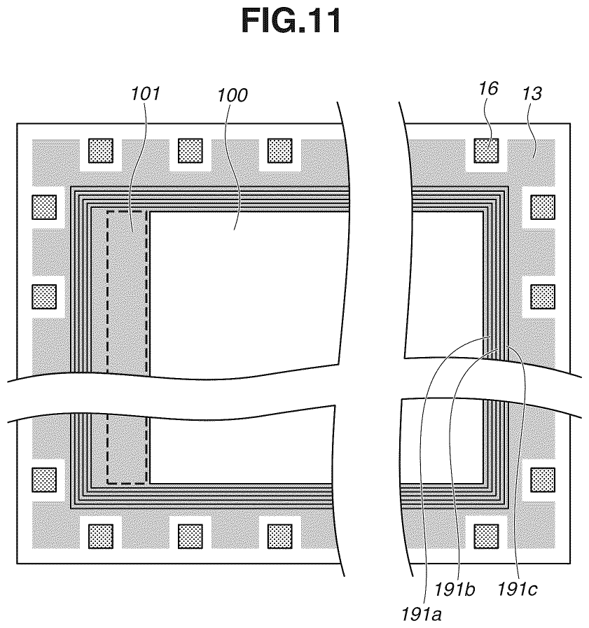

FIG. 10 is a schematic cross-sectional view illustrating a laminated rear-surface irradiation photoelectric conversion apparatus according to a sixth exemplary embodiment. FIG. 11 is a schematic plan view illustrating the light-shielding layer 13 viewed from the light-incident surface of the photoelectric conversion apparatus according to the sixth exemplary embodiment. FIG. 11 also illustrates the positions of via plugs to make it easier to grasp the positions of via plugs in a planar view. The sixth exemplary embodiment differs from the fifth exemplary embodiment in that the semiconductor region 161 of the second conductivity type and the light-shielding layer 13 are connected via plugs 191a, 191b, and 191c, and that color filters of different colors are disposed. The present exemplary embodiment is substantially the same as the fifth exemplary embodiment except for these points, and redundant descriptions thereof will be omitted.

As illustrated in FIG. 10, the light-shielding layer 13 and the semiconductor region 161 of the second conductivity type are electrically connected with the via plugs 191a, 191b, and 191c. As described above with reference to the fourth exemplary embodiment, a high voltage as a negative voltage having a larger absolute value than −20 V is applied to the semiconductor region 161 of the second conductivity type. This voltage is also applied to the light-shielding layer 13 via the via plugs 191a, 191b, and 191c. This means that the light-shielding layer 13 and the semiconductor region 161 have the same potential. With a large potential difference between the light-shielding layer 13 and the semiconductor region 161, a dielectric breakdown may possibly occur in the insulation film disposed between the light-shielding layer 13 and the semiconductor region 161. However, the present exemplary embodiment enables preventing a dielectric breakdown in the insulation film.

Although, referring to FIG. 10, the light-shielding layer 13 and the semiconductor region 161 are connected via the three different via plugs, they may be connected via one, two, or four or more via plugs.

As illustrated in FIG. 10, preferably, the semiconductor region 161 is disposed so that its width is larger than the width of the pixel region including the OB pixel region 101. More specifically, preferably, the semiconductor region 161 is disposed so that its width is larger than the width of the pixel region in a cross-sectional view. This makes it easier to connect the light-shielding layer 13 and the semiconductor region 161 via via plugs. Although FIG. 10 illustrates only one cross-section, preferably, the semiconductor layer 161 is disposed so that its width is larger than the width of the pixel region 100 also in a cross-section in a direction intersecting with the cross-section in FIG. 10.

The semiconductor region 152 of the second conductivity type for forming an avalanche multiplication region of the APD may be disposed in the entire pixel region in a planar view. In this case, the edge of the semiconductor region 152 of the second conductivity type may be included in the semiconductor region 161 of the second conductivity type or in contact with the outer periphery of the semiconductor region 161 of the second conductivity type.

Referring to FIG. 11, the light-shielding layer 13 is disposed so as to partially surround the opening of the pad 16 in a planar view. For example, if the opening is a square, the light-shielding layer 13 is disposed so as to surround three sides out of the four sides of the square in a planar view. Preferably, the light-shielding layer 13 is disposed up to the edge of the semiconductor element layer 11 as far as possible.

As illustrated in FIG. 11, the via plugs 191a, 191b, and 191c are disposed so as to surround the effective pixel region 100 and the OB pixel region 101 in a planar view. The via plugs 191a and 191b are connected with the semiconductor region 161 also in a cross-section in a direction intersecting with the cross-section in FIG. 10. The via plugs 191a, 191b, and 191c are disposed so as to surround the entire circumference of the effective pixel region 100 and the OB pixel region 101 in this way. This makes it easier to prevent a dielectric breakdown in the insulation film between the light-shielding layer 13 and the semiconductor region 161 regardless of the position of the light-shielding layer 13.

As illustrated in FIG. 12, the light-shielding layer 13 may be disposed so as to surround the entire circumference of the pad 16 in a planar view. This enables reducing the amount of light entering the semiconductor element layer 11 to a further extent than the example illustrated in FIG. 11.

Although FIG. 12 does not illustrate the via plugs 191a, 191b, and 191c illustrated in FIG. 11, the via plugs 191a, 191b, and 191c may be disposed, and the OB pixel region 101 illustrated in FIG. 11 may be disposed.

Like the fifth exemplary embodiment, the present exemplary embodiment enables accurately detecting the black level reference value while preventing the formation of an avalanche multiplication region between the semiconductor regions 161 and 171. Since a high voltage is not applied to the semiconductor element layer 23 of the substrate 2, the reliability of the photoelectric conversion apparatus can be easily ensured when the APD is used. Further, the present exemplary embodiment enables preventing a dielectric breakdown in the insulation film disposed between the light-shielding layer 13 and the semiconductor region 161.

### Seventh Exemplary Embodiment

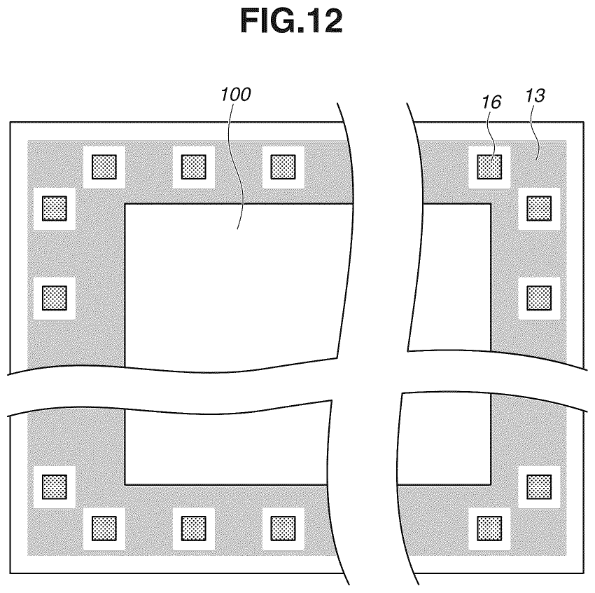

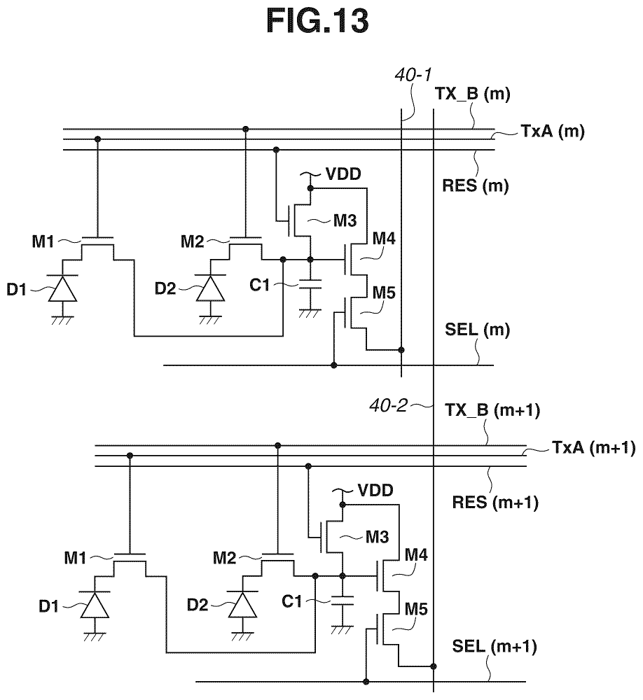

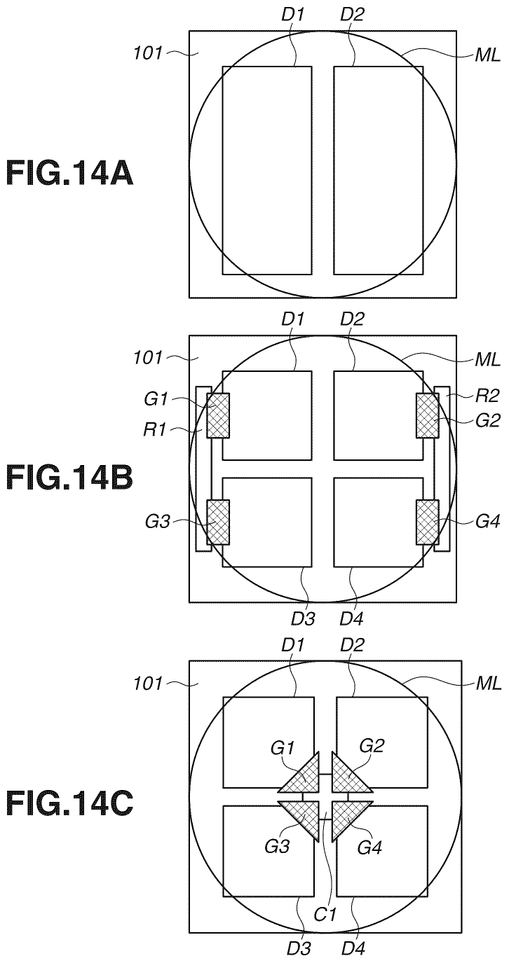

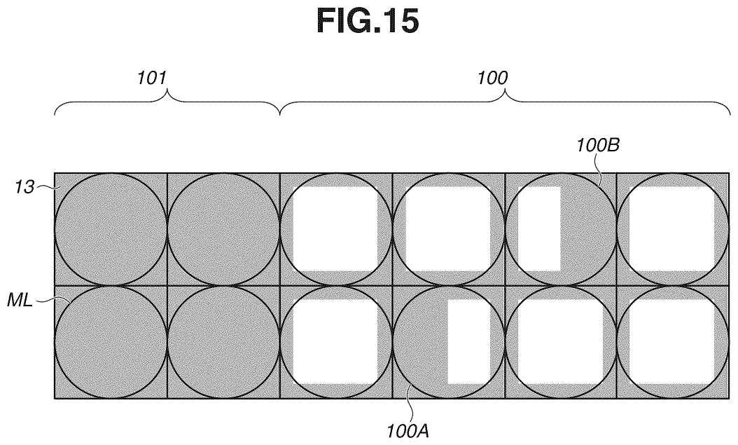

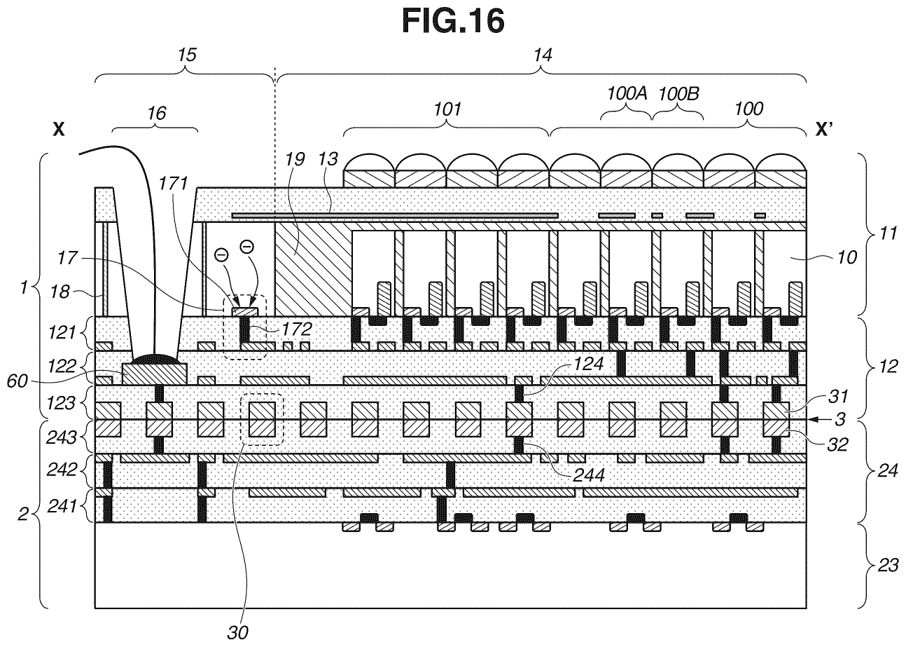

FIG. 13 illustrates an equivalent circuit of pixels according to a seventh exemplary embodiment. FIGS. 14A to 14C illustrate a configuration of a pixel according to the seventh exemplary embodiment. FIG. 15 is a schematic plan view illustrating the well region 14 according to the seventh exemplary embodiment. FIG. 16 is a schematic cross-sectional view taken along the X-X′ line of FIG. 6. The present exemplary embodiment differs from the first to third exemplary embodiments in that each of the pixels 10 has a plurality of photoelectric conversion units to enable focus detection based on the phase difference detection method. The present exemplary embodiment is substantially the same as other exemplary embodiments except for this point and the following point, and redundant descriptions thereof will be omitted.

FIG. 13 illustrates an example of a circuit diagram including the pixels 10 in two rows by one column out of the pixels 10 disposed in the effective pixel region 100.

A pixel 10 includes photodiodes D1 and D2 as photoelectric conversion units, transfer transistors M1 and M2, an electric charge conversion unit C1, a reset transistor M3, an amplification transistor M4, and a selection transistor M5. The transfer transistor M1 is disposed in the electrical path between the node (connected with the electric charge conversion unit C1, the reset transistor M3, and the amplification transistor M4) and the photodiode D1. The transfer transistor M2 is disposed in the electrical path between the node (connected with the electric charge conversion unit C1, the reset transistor M3, and the amplification transistor M4) and the photodiode D2. The electric charge conversion unit C1 is also referred to as a floating diffusion unit (FD unit). The power voltage VDD is applied to the reset transistor M3 and the amplification transistor M4. The selection transistor M5 is disposed in the electrical path between the amplification transistor M4 and a vertical output line 40. The amplification transistor M4 is electrically connected with the vertical output line 40 via the selection transistor M5. The electric charge conversion unit C1 includes a floating diffusion capacitance disposed in the semiconductor substrate, and a parasitic capacitance of the electrical path ranging from the transfer transistor M1 to the amplification transistor M5 through the floating diffusion capacitance. Signals RES, Tx_A, and SEL are supplied from a vertical scanning circuit (not illustrated).

The photodiodes D1 and D2 are disposed in association with one microlens ML, as illustrated in FIG. 14A. More specifically, the photodiodes D1 and D2 are disposed so as to receive light penetrating one microlens ML. This enables performing focus detection based on the phase difference detection method.

The pixel configuration according to the present exemplary embodiment is not limited to the configuration illustrated in FIGS. 13 and 14A. A pixel may include three or more photoelectric conversion units for each microlens ML. For example, FIGS. 14B and 14C illustrate configurations where four different photodiodes D1 to D4 are disposed as four photoelectric conversion units for one microlens ML. A transfer transistor is disposed in association with each of the photodiodes D1 to D4. Gates G1 to G4 are the gate electrodes of the transfer transistors. Referring to FIG. 14B, the gates G1 and G3 transfer electric charges to a pixel readout circuit R1, and the gates G2 and G4 transfer electric charges to a pixel readout circuit R2. Each of the pixel readout circuits R1 and R2 is disposed with the capacitive element C1 illustrated in FIG. 13. The reset transistor M3, the amplification transistor M4, and the selection transistor M5 illustrated in FIG. 13 may be disposed in each of the pixel readout circuits R1 and R2 or disposed in either one of the pixel readout circuits R1 and R2.

FIG. 14C illustrates a form in which four gates G1 to G4 are disposed so as to transfer electric charges to one capacitive element C1. This form also enables the present exemplary embodiment to be suitably implemented.

FIG. 15 is a schematic plan view illustrating the well region 14 according to the seventh exemplary embodiment. The light-shielding layer 13 disposed on the well region 14 shields the OB pixel region 101 from light. Portions on the light-shielding layer 13 overlapping with the effective pixel region 100 in a planar view are disposed with openings corresponding to pixels, and light is incident on the pixel corresponding to each opening.

In the above-described configuration, light is incident on both the photodiodes D1 and D2 disposed in association with one microlens ML.

As another exemplary embodiment of the present disclosure, one of the photodiodes D1 and D2 is light-shielded and the other photodiode is subjected to light incidence. Referring to FIG. 15, the light-shielding layer 13 is disposed with an opening corresponding to a pixel 100A including the photodiode D2 in FIG. 14A and an opening corresponding to a pixel 100B including the photodiode D1 in FIG. 14A. In this case, one of the photodiodes D1 and D2 is subjected to light incidence for one part of the pixels 10, and the other photodiode is subjected to light incidence for another part of the pixels 10. Even this configuration enables focus detection based on the phase difference detection method by reading signals of one part of the pixels 10 and another part of the pixels 10. The read signals are used, for example, for focus detection by a detection unit on the second substrate. Only by changing the pattern of the light-shielding layer 13, pixels for phase difference detection can be formed without increasing the number of processes. Although, in this example, the pixel 100A is provided with a plurality of photodiodes D1 and D2, the pixel 100A may be provided with only one photodiode. In this case, for one part of the pixels 10, one portion of the photodiode is light-shielded and the other portion thereof is subjected to light incidence. For another part of the pixels 10, one portion at another position of the photodiode is light-shielded and the other portion is subjected to light incidence. In this case, the light-shielded area is larger than that of photodiodes used for image capturing. Output signals of the pixels 10 having such light-shielded photodiodes enables focus detection. According to the present exemplary embodiment, disposing the electric charge discharge region enables reducing electric charges entering a focus detection signal and more preferably performing focus detection.

FIG. 16 is a schematic cross-sectional view taken along the line X-X′ of FIG. 6. Effective pixels disposed in the effective pixel region 100 include the pixels 100A and 100B. Referring to the cross-sectional view illustrated in FIG. 16, the structure of the pad 16 has been changed from that in the cross-sectional view illustrated in FIG. 7.

The wiring structure 12 includes the first wiring layer 121, the second wiring layer 122, and connecting portions 31. The wiring structure 24 includes the first wiring layer 242, the second wiring layer 241, and the connecting portions 32. Each wiring layer is what is called a copper wiring.

In the wiring structures 12 and 24, the first wiring layer includes a conductor pattern mainly composed of copper. The conductor pattern of the wiring layer 1 has a single damascene structure. A contact is disposed for an electrical connection between the first wiring layer and the semiconductor layer 11. The contact is a conductor pattern mainly composed of tungsten. The second wiring layer includes a conductor pattern mainly composed of copper. The conductor pattern of the second wiring layer has a dual damascene structure including portions functioning as wiring and portions functioning as vias.

A pad electrode 60 included in the pad 16 is a conductor pattern mainly composed of aluminum. Although, referring to FIG. 16, the pad electrode 60 is disposed in the second wiring layer of the wiring structure 12 and positioned between the first and second surfaces of the first substrate, the position of the pad electrode 60 is not limited thereto.

The pad electrode 60 has a first surface and a second surface as the surface opposite to the first surface. The first surface is partially exposed through an opening of the semiconductor layer. The exposed portion of the pad electrode 60 can function as a connecting portion with an external terminal, i.e., what is called a pad. The pad electrode 60 is connected with a plurality of conductors mainly composed of copper on the second surface.

As a form different from the present exemplary embodiment, the portion not exposed on the first surface of the pad electrode 60 can have an electrical connecting portion. For example, the pad electrode 60 may have a via made of a conductor mainly composed of aluminum, and may be electrically connected with a conductor mainly composed of copper disposed on the first surface, via the via. The pad electrode 60 may be connected with the first wiring layer of the wiring structure by a conductor mainly composed of tungsten on the first surface.

The pad electrode 60 can be formed, for example, by forming an insulator covering the wiring layer, removing a part of the insulator, forming a film as the pad electrode 60 mainly composed of aluminum, and then patterning the film. By forming a copper wiring and then forming the pad electrode 60, the pad electrode 60 having a thick film can be formed while maintaining the evenness of the fine copper wiring.

Although, in the above-described case according to the present exemplary embodiment, the pad electrode 60 is included in the wiring structure 12, the pad electrode 60 may be included in the wiring structure 24. The position where the pad electrode 60 is disposed is not limited thereto but may be either one of the wiring structure 121 or 122. The material and structure of the wiring layers of the wiring structures 121 and 122 are not limited to the above-described examples but may further include a conductor layer between the wiring layer and the semiconductor layer. A stack contact structure is included in which two contact layers are laminated.

### Eighth Exemplary Embodiment

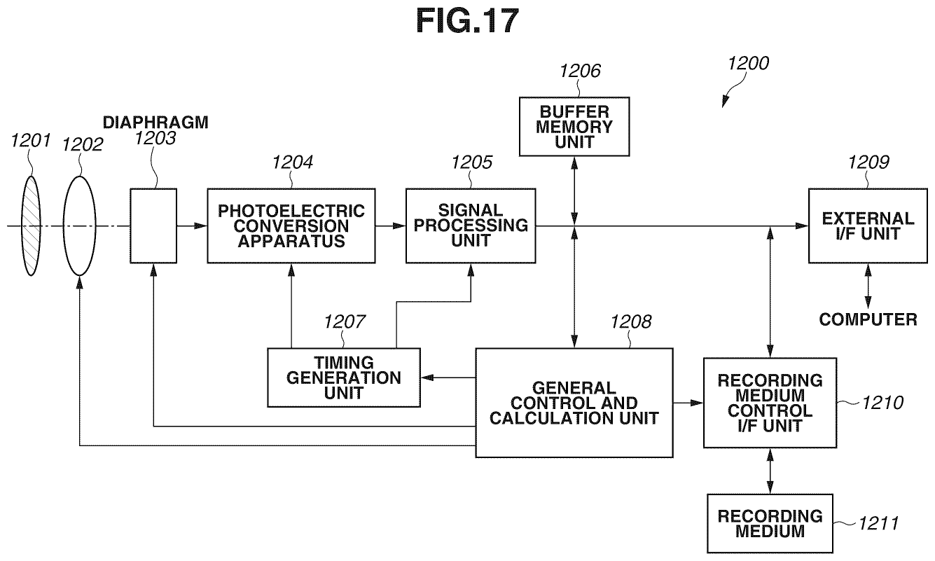

FIG. 17 is a block diagram illustrating a configuration of a photoelectric conversion system 1200 according to an eighth exemplary embodiment. The photoelectric conversion system 1200 according to the present exemplary embodiment includes a photoelectric conversion apparatus 1204. Any one of the photoelectric conversion apparatuses according to the above-described exemplary embodiments is applicable to the photoelectric conversion apparatus 1204. For example, the photoelectric conversion system 1200 can be used as an imaging system. Specific examples of imaging systems include digital still cameras, digital camcorders, and monitoring cameras. Referring to the example illustrated in FIG. 17, a digital still camera is used as the photoelectric conversion system 1200.

The photoelectric conversion system 1200 illustrated in FIG. 17 includes a photoelectric conversion apparatus 1204, a lens 1202 for focusing the optical image of a subject on the photoelectric conversion apparatus 1204, a diaphragm 1203 for varying the amount of light passing through the lens 1202, and a barrier 1201 for protecting the lens 1202. The lens 1202 and the diaphragm 1203 form an optical system for condensing light to the photoelectric conversion apparatus 1204.

The photoelectric conversion system 1200 includes a signal processing unit 1205 for processing an output signal output from the photoelectric conversion apparatus 1204. The signal processing unit 1205 subjects the input signal to various kinds of signal processing such as correction and compression as required and outputs the resultant signal. The photoelectric conversion system 1200 further includes a buffer memory unit 1206 for temporarily storing image data, and an external interface unit (external I/F unit) 1209 for communicating with an external computer. The photoelectric conversion system 1200 further includes a recording medium 1211 such as a semiconductor memory for recording and reading imaging data, and a recording medium control interface unit (recording medium control I/F unit) 1210 for recording and reading data to/from the recording medium 1211. The recording medium 1211 may be built in the photoelectric conversion system 1200 or attachable to and detachable from the photoelectric conversion system 1200. Communication between the recording medium control I/F unit 1210 and the recording medium 1211 and communication with the external I/F unit 1209 may be wirelessly performed.

The photoelectric conversion system 1200 further includes a general control and calculation unit 1208 for performing various calculations and controlling the entire digital still camera, and a timing generation unit 1207 for outputting various timing signals to the photoelectric conversion apparatus 1204 and the signal processing unit 1205. The timing signals may be input from the outside. The photoelectric conversion system 1200 only needs to include at least the photoelectric conversion apparatus 1204, and the signal processing unit 1205 for processing output signals output from the photoelectric conversion apparatus 1204. As described above with reference to the fourth exemplary embodiment, the timing generation unit 1207 may be mounted on the photoelectric conversion apparatus 1204. The general control and calculation unit 1208 and the timing generation unit 1207 may be configured to perform a part or whole of control functions of the photoelectric conversion apparatus 1204.

The photoelectric conversion apparatus 1204 outputs an image signal to the signal processing unit 1205. The signal processing unit 1205 subjects the image signal output from the photoelectric conversion apparatus 1204 to predetermined signal processing, and outputs image data. The signal processing unit 1205 generates an image by using the image signal. The signal processing unit 1205 may subject the signal output from the photoelectric conversion apparatus 1204 to distance measurement calculation. The signal processing unit 1205 and the timing generation unit 1207 may be mounted on the photoelectric conversion apparatus 1204. More specifically, the signal processing unit 1205 and the timing generation unit 1207 may be disposed in a substrate with pixels arranged therein or in another substrate. Configuring an imaging system by using the photoelectric conversion apparatus 1204 according to each of the above-described exemplary embodiments enables implementing a photoelectric conversion system capable of acquiring images with higher quality.

### Ninth Exemplary Embodiment

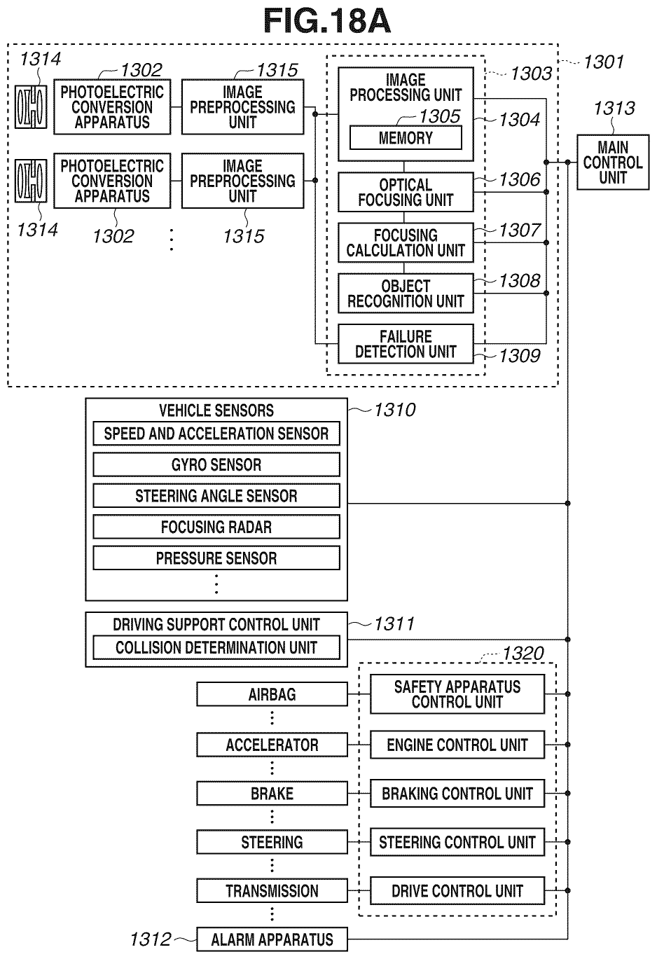

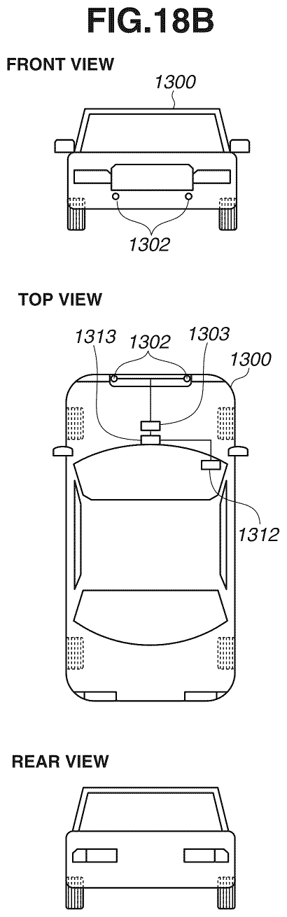

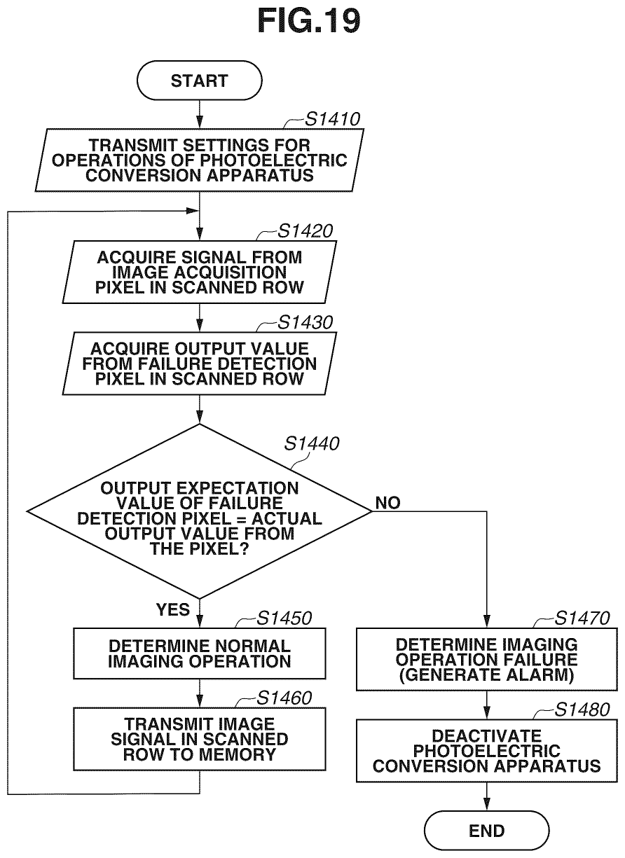

A photoelectric conversion system and a moving object according to a ninth exemplary embodiment will be described below with reference to FIGS. 18A, 18B, and 19. FIGS. 18A and 18B are schematic views illustrating examples of configurations of the photoelectric conversion system and the moving object, respectively, according to the ninth exemplary embodiment. FIG. 19 is a flowchart illustrating operations of the photoelectric conversion system according to the present exemplary embodiment. According to the present exemplary embodiment, an on-vehicle camera is used as an example of the photoelectric conversion system.

FIGS. 18A and 18B illustrate examples of a vehicle system and the photoelectric conversion system for performing imaging mounted on the vehicle system. A photoelectric conversion system 1301 includes a photoelectric conversion apparatus 1302, an image preprocessing unit 1315, an integrated circuit 1303, and an optical system 1314. The optical system 1314 forms an optical image of the subject on the photoelectric conversion apparatus 1302. The photoelectric conversion apparatus 1302 converts the optical image formed by the optical system 1314 into an electrical signal. The photoelectric conversion apparatus 1302 is the photoelectric conversion apparatus according to one of the above-described exemplary embodiments. The image preprocessing unit 1315 subjects the signal output from the photoelectric conversion apparatus 1302 to predetermined signal processing. The function of image preprocessing unit 1315 may be incorporated in the photoelectric conversion apparatus 1302. The photoelectric conversion system 1301 includes at least two sets of the optical system 1314, the photoelectric conversion apparatus 1302, and the image preprocessing unit 1315. The output from the image preprocessing unit 1315 of each set is input to the integrated circuit 1303.

The integrated circuit 1303, an integrated circuit for imaging system applications, includes an image processing unit 1304 including a memory 1305, an optical focusing unit 1306, a focusing calculation unit 1307, an object recognition unit 1308, and a failure detection unit 1309. The image processing unit 1304 subjects the output signal of the image preprocessing unit 1315 to such image processing as development processing and defect correction. The memory 1305 primarily stores captured images, and stores defect positions of imaging pixels. The optical focusing unit 1306 focuses the subject and performs distance measurement. The focusing calculation unit 1307 calculates distance measurement information based on a plurality of image data pieces acquired by a plurality of the photoelectric conversion apparatuses 1302. The object recognition unit 1308 recognizes subjects such as vehicles, paths, traffic signs, and persons. The failure detection unit 1309, upon detection of a failure of the photoelectric conversion apparatus 1302, issues an alarm to a main control unit 1313.

The integrated circuit 1303 may be implemented by a specially designed hardware component, a software module, or a combination of both. The integrated circuit 1303 may also be implemented by a Field Programmable Gate Array (FPGA), an Application Specific Integrated Circuit (ASIC), or a combination of both.

The main control unit 1313 totally controls operations of the photoelectric conversion system 1301, vehicle sensors 1310, and a control unit 1320. A certain method that does not use the main control unit 1313 may also be applicable. In this method, each of the photoelectric conversion system 1301, the vehicle sensors 1310, and the control unit 1320 has a communication interface and transmits and receives control signals via a communication network (e.g., based on a Controller Area Network (CAN) standard).

The integrated circuit 1303 has a function of receiving control signals from the main control unit 1313 and a function of transmitting control signals and setting values to the photoelectric conversion apparatus 1302 via its own control unit.

The photoelectric conversion system 1301 connected to the vehicle sensors 1310 is capable of detecting vehicle running states (including the vehicle speed, yaw rate, and steering angle), the environment outside the vehicle, and states of other vehicles and obstacles. The vehicle sensors 1310 also serve as distance information acquisition units for acquiring information about the distance to a target. The photoelectric conversion system 1301 is connected to a driving support control unit 1311 for performing various driving support functions such as automatic steering, automatic cruising, and collision prevention functions. In particular, a collision determination function presumes and determines a collision with other vehicles and obstacles based on detection results by the photoelectric conversion system 1301 and the vehicle sensors 1310. This function performs collision avoidance control when a collision is presumed and activates a safety apparatus when a collision takes place.

The photoelectric conversion system 1301 is also connected to an alarm apparatus 1312 for issuing an alarm to the driver based on a result of the determination by a collision determination unit. For example, if the possibility of collision is determined to be high as a result of the determination by the collision determination unit, the main control unit 1313 performs vehicle control for avoiding a collision and reducing damages, for example, by applying brakes, releasing the accelerator, or restraining the engine power. The alarm apparatus 1312 warns the driver by generating an alarm sound, displaying alarm information on the display screen of a car navigation system or meter panel, or applying a vibration to the seat belt or steering wheel.

According to the present exemplary embodiment, the photoelectric conversion system 1301 captures images of the surrounding of the vehicle, for example, images ahead of or behind the vehicle. FIG. 18B illustrates an example of a layout of the photoelectric conversion system 1301 in a case where images ahead of the vehicle are to be captured by the photoelectric conversion system 1301.

The two photoelectric conversion apparatuses 1302 are disposed at anterior positions of a vehicle 1300. More specifically, assuming that the center line for the forward/backward moving direction or the profile (such as the width) of the vehicle 1300 is a symmetric axis, disposing the two photoelectric conversion apparatuses 1302 in line symmetry with respect to the symmetric axis is desirable in acquiring information about the distance between the vehicle 1300 and the target and determining the possibility of a collision. Desirably, the photoelectric conversion apparatuses 1302 are disposed not to disturb the driver's sight when the driver views the situation outside the vehicle 1300 from the driver's seat. Desirably, the alarm apparatus 1312 is disposed at a position that easily comes in the driver's sight.

A failure detection operation of the photoelectric conversion apparatuses 1302 in the photoelectric conversion system 1301 will be described below with reference to FIG. 19. The photoelectric conversion apparatus 1302 performs the failure detection operation according to steps S1410 to S1480 in the flowchart illustrated in FIG. 19.

In step S1410, each photoelectric conversion apparatus 1302 performs start-up setting processing. More specifically, settings for operations of the photoelectric conversion apparatus 1302 are transmitted from the outside of the photoelectric conversion system 1301 (e.g., the main control unit 1313) or the inside thereof to start the imaging operation and the failure detection operation of the photoelectric conversion apparatus 1302.

In step S1420, the main control unit 1313 acquires a pixel signal from an effective pixel. In step S1430, the main control unit 1313 acquires the output value from a failure detection pixel arranged for failure detection. The failure detection pixel includes a photoelectric conversion portion like the effective pixel. A predetermined voltage is written to the photoelectric conversion portion. The failure detection pixel outputs a signal corresponding to the voltage written to the photoelectric conversion portion. Steps S1420 and S1430 may be reversed.

In step S1440, the main control unit 1313 determines whether the output expectation value of the failure detection pixel coincides with the actual output value of the failure detection pixel. When the output expectation value coincides with the actual output value as a result of the determination (YES in step S1440), the processing proceeds to step S1450. In step S1450, the main control unit 1313 determines that the imaging operation is normally performed. Then, the processing proceeds to step S1460. In step S1460, the main control unit 1313 transmits the pixel signal of a scanned row to the memory 1305 to primarily store the pixel signal. Then, the processing returns to step S1420. The main control unit 1313 continues the failure detection operation. On the other hand, when the output expectation value does not coincide with the actual output value (NO in step S1440), the processing proceeds to step S1470. In step S1470, the main control unit 1313 determines that the imaging operation fails and then issues an alarm to the main control unit 1313 or the alarm apparatus 1312. The alarm apparatus 1312 displays that a failure has been detected on the display unit. In step S1480, the main control unit 1313 deactivates the photoelectric conversion apparatus 1302 and then ends the operation of the photoelectric conversion system 1301.

In the flowchart according to the present exemplary embodiment, a loop is formed for each row. However, a loop may be formed for a plurality of rows, or the failure detection operation may be performed for each frame. The alarm issued in step S1470 may be notified to the outside of the vehicle via a wireless network.

Although the present exemplary embodiment has been described above centering on control for avoiding a collision with other vehicles, it is also applicable to automatic driving control of following another vehicle or automatic driving control of retaining the vehicle within the lane. The photoelectric conversion system 1301 is applicable not only to vehicles but also to moving objects (moving apparatuses) such as vessels, airplanes, and industrial robots. In addition, the photoelectric conversion system 1301 is applicable not only to moving objects but also to intelligent transport systems (ITS's) and a wide range of apparatuses utilizing object recognition.

The photoelectric conversion apparatus of the present invention may be configured to acquire various kinds of information including the distance information.

The present invention is not limited to the above embodiments and various changes and modifications can be made within the spirit and scope of the present invention. Therefore, to apprise the public of the scope of the present invention, the following claims are made.

The present invention enables providing a laminated photoelectric conversion apparatus capable of preventing surplus electric charges from entering the OB region and more accurately detecting a black level reference signal.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A photoelectric conversion apparatus comprising:
a first substrate having a first semiconductor element layer including a plurality of photoelectric conversion units and a well with the plurality of photoelectric conversion units disposed; and
a second substrate having a second semiconductor element layer including a circuit for processing signals acquired by the plurality of photoelectric conversion units,
wherein the first and second substrates are laminated,
wherein the first semiconductor element layer has an effective pixel region having the plurality of photoelectric conversion units, an optical black pixel region disposed between the effective pixel region and an edge of the first semiconductor element layer, having the plurality of photoelectric conversion units, and an outer periphery region disposed between the optical black pixel region and the edge of the first semiconductor element layer,
wherein the effective pixel region includes a photoelectric conversion unit having a larger light-shielded area than other photoelectric conversion units out of the plurality of photoelectric conversion units,
wherein the optical black pixel region overlaps with a light-shielding region including a light-shielding layer, but the outer periphery region does not overlap with the light-shielding region in a planar view,
wherein the outer periphery region is provided with an electric charge discharge region including a semiconductor region of the same conductivity type as signal electric charges, and
wherein the electric charge discharge region is supplied with a fixed potential.

2. The photoelectric conversion apparatus according to claim 1, wherein a conductivity type of the outer periphery region is an N-type, and a positive potential is applied to the electric charge discharge region.

3. The photoelectric conversion apparatus according to claim 1, wherein a conductivity type of the outer periphery region is a P-type, and a ground potential is applied to the electric charge discharge region.

4. The photoelectric conversion apparatus according to claim 1, wherein the light-shielding region overlaps with a part of the well and outer periphery region in a planar view.

5. The photoelectric conversion apparatus according to claim 4, wherein the well is not exposed from the light-shielding region in a planar view.

6. The photoelectric conversion apparatus according to claim 1,
wherein a pad for making an electrical connection between the photoelectric conversion apparatus and outside is disposed in the outer periphery region, and
wherein the electric charge discharge region is disposed between the pad and the well.

7. The photoelectric conversion apparatus according to claim 6, wherein an element separating portion is disposed to penetrate through the first semiconductor element layer between the electric charge discharge region and the pad.

8. The photoelectric conversion apparatus according to claim 7, wherein the element separating portion has a region embedded with an insulating material.

9. The photoelectric conversion apparatus according to claim 6, wherein a distance between a center of the pad and the light-shielding layer is 30 μm or more and 200 μm or less.

10. The photoelectric conversion apparatus according to claim 6,
wherein the photoelectric conversion unit is an avalanche photodiode (APD), and
wherein a distance between the well and the electric charge discharge region is 1 μm or more.

11. The photoelectric conversion apparatus according to claim 6,
wherein the photoelectric conversion unit is an APD, and
wherein a distance between the well and the electric charge discharge region causes no avalanche multiplication.

12. The photoelectric conversion apparatus according to claim 10, wherein the pad is connected with a wiring layer disposed in the first substrate.

13. The photoelectric conversion apparatus according to claim 6, wherein, in the first semiconductor element layer, no circuit element is disposed between the pad and the well.

14. The photoelectric conversion apparatus according to claim 6,
wherein a wiring mainly composed of copper is disposed between the first and second substrates, and
wherein the pad is mainly composed of aluminum.

15. The photoelectric conversion apparatus according to claim 1, wherein a detection unit for performing focus detection by using signals output from the plurality of photoelectric conversion units is disposed on the second substrate.

16. The photoelectric conversion apparatus according to claim 1, wherein, out of the plurality of photoelectric conversion units, a photoelectric conversion unit having a larger light-shielded area than other photoelectric conversion units outputs a signal to be used for focus detection.

17. A photoelectric conversion system comprising:
the photoelectric conversion apparatus according to claim 1; and
a signal processing unit configured to process a signal output by the photoelectric conversion apparatus.

18. A moving object comprising:
the photoelectric conversion apparatus according to claim 1;
a distance information acquisition unit configured to acquire information about a distance to a target based on a signal from the photoelectric conversion apparatus; and
a control unit configured to control the moving object based on the distance information.
